(19) United States
(12) Patent Application Publication
(10) Pub. No.: US 2023/0013113 A1
(43) Pub. Date: Jan. 19, 2023

(54) SURPLUS POWER CAPACITY CALCULATION SYSTEM, MONITORING APPARATUS, SURPLUS POWER CAPACITY CALCULATION METHOD AND PROGRAM

(71) Applicant: Nippon Telegraph and Telephone Corporation, Tokyo (JP)

(72) Inventors: Atsushi Sakurai, Musashino-shi, Tokyo (JP); Masaki NIWA, Musashino-shi, Tokyo (JP); Tomomi NAGAO, Musashino-shi, Tokyo (JP); Yuriko Tanaka, Musashino-shi, Tokyo (JP)

(21) Appl. No.: 17/783,042

(22) PCT Filed: Dec. 13, 2019
(86) PCT No.: PCT/JP2019/049008

§ 371 Date: Jun. 7, 2022

(51) Int. Cl. G06F 1/28; H02J 13/00; G01R 21/133

(52) U.S. Cl. CPC G06F 1/28; H02J 13/00002; G01R 21/133

(57) ABSTRACT

A surplus power capacity calculation system includes: a measurement unit that measures a total value of electric power supplied from a power supply device to a plurality of ICT devices; and a monitoring device that calculates a surplus power capacity of the power supply device. The monitoring device includes: a calculation unit that acquires the total value and a processing amount of each of the plurality of ICT devices, estimates an increase in power consumption on the basis of the processing amount when each ICT device performs processing with a maximum processing amount, and subtracts a sum of the increase and the total value from a maximum power consumption amount of the power supply device to calculate the surplus power capacity.

### TECHNICAL FIELD

The present invention relates to a technique for calculating the surplus power capacity of a power supply device.

### BACKGROUND ART

The power consumption of an ICT (Information and Communication Technology) device such as a server varies depending on the amount of processing executed by the ICT device (see Reference Document 1, the reference document name is described at the end of the specification).

The ICT device generally has built-in management software that measures and records the device state such as the above-mentioned processing amount. With the management software, the ICT device can transfer the device status to a monitoring center or the like as needed by an operator (see NPL 1).

In recent years, virtualization technologies such as network virtualization (NFV: Network Functions Virtualization) have become widespread. In virtualization technology, a large amount of general-purpose hardware is prepared to secure a large number of resource pools (see Reference Document 2).

### CITATION LIST

### Non Patent Literature

[NPL 1] CISCO web site “Power Management for Catalyst 6000 Series Switches”, https://www.cisco.com/c/ja_jp/support/docs/switches/catalyst-6 500-series-switches/22389-142.pdf, Internet, searched on Dec. 6, 2019

### SUMMARY OF THE INVENTION

### Technical Problem

The processing amount of the ICT device varies depending on the demand for network services and the like, and the power consumption of the ICT device also varies accordingly. In particular, when an operation such as a healing function of network virtualization (NFV) (see Reference Document 3) is performed in which processing is transferred to another hardware when a certain hardware fails, the power consumption varies greatly.

If there is a possibility that the power consumption varies significantly, it is conceivable to provide a large-scale power supply device with a margin, but this may result in excessive cost. On the other hand, when a power supply device of a scale on the basis of actual values or the like is provided, the surplus power capacity decreases as the processing amount of the ICT device varies, and there is a possibility that a failure occurs due to insufficient power supply when the healing function is performed or in other cases.

Therefore, in a power supply device that has many ICT devices under its control, it is necessary to grasp the surplus power capacity to add a power supply device and appropriately control the processing amount of the ICT devices so that the power can be sufficiently supplied in the event of a failure.

However, in the prior art, in order to grasp the surplus power capacity of a power supply device, it is necessary to install and manage sensors for grasping the power consumption of individual ICT devices, which is a problem that it is costly.

The present invention has been made in view of the above-described problems, and an object thereof is to provide a technique for enabling the surplus power capacity of a power supply device to be obtained without individually measuring the power consumption of a plurality of ICT devices in a power supply device that supplies electric power to the plurality of ICT devices.

### Means for Solving the Problem

According to the disclosed technique, there is provided a surplus power capacity calculation system including: a measurement unit that measures a total value of electric power supplied from a power supply device to a plurality of ICT devices; and a monitoring device that calculates a surplus power capacity of the power supply device, wherein the monitoring device includes: a calculation unit that acquires the total value and a processing amount of each of the plurality of ICT devices, estimates an increase in power consumption on the basis of the processing amount when each ICT device performs processing with a maximum processing amount, and subtracts a sum of the increase and the total value from a maximum power consumption amount of the power supply device to calculate the surplus power capacity.

### Effects of the Invention

According to the disclosed technology, a technique for enabling the surplus power capacity of a power supply device to be obtained without individually measuring the power consumption of a plurality of ICT devices in a power supply device that supplies electric power to the plurality of ICT devices is provided.

### BRIEF DESCRIPTION OF DRAWINGS

FIG. 1 is a diagram illustrating a configuration of a system according to an embodiment of the present invention.

FIG. 2 is a diagram illustrating an ICT device efficiency characteristic table.

FIG. 3 is a diagram illustrating a power measurement table.

FIG. 4 is a diagram illustrating an ICT device table.

FIG. 5 is a diagram illustrating an example of a hardware configuration of a monitoring device.

FIG. 6 is a diagram illustrating a flowchart of operation.

FIG. 7 is a diagram illustrating a flowchart of operation.

FIG. 8 is a diagram illustrating a configuration of a system according to an example.

FIG. 9 is a diagram illustrating an ICT device efficiency characteristic table.

FIG. 10 is a diagram illustrating a power measurement table.

FIG. 11 is a diagram illustrating an ICT device table.

### DESCRIPTION OF EMBODIMENTS

Hereinafter, embodiments of the present invention will be described with reference to the drawings. The embodiments described below are merely examples, and the embodiments to which the present invention is applied are not limited to the following embodiments.

### System Configuration Example

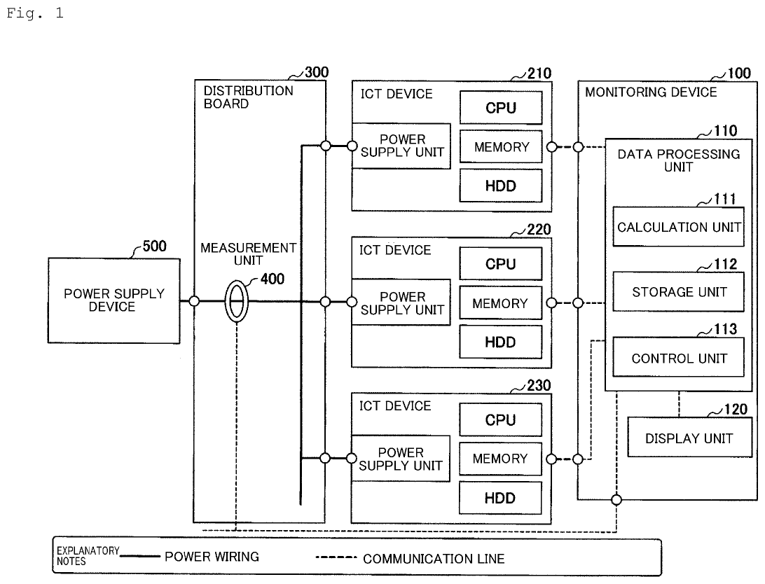

FIG. 1 illustrates an example illustrating a configuration of a system according to an embodiment of the present invention. As illustrated in FIG. 1, the system includes a monitoring device 100, ICT devices 210 to 230, a distribution board 300, and a power supply device 500. This system may be referred to as a surplus power capacity calculation system.

The place where the system illustrated in FIG. 1 is provided is, for example, a communication machine room, a computer room, a data center, and the like, but is not limited thereto. Although FIG. 1 illustrates one distribution board 300 and one power supply device 500, a plurality of distribution boards and a plurality of power supply devices may be provided. Further, it is an example in which three ICT devices are connected to the distribution board 300.

The monitoring device 100, the ICT devices 210 to 230, the distribution board 300, and the power supply device 500 do not all need to be in the same place. For example, the monitoring device 100 may be located at a location remote from the location where the ICT devices 210 to 230 and the like are provided.

The power supply device 500 is, for example, a device that receives electric power from a commercial electric power system and supplies electric power to the distribution board 300. The power supply device 500 may be connected to a storage battery. In this way, the power supply device 500 can supply electric power even during a commercial power outage.

The power supply device 500 may be an uninterruptible power supply (UPS) that outputs AC power, or a rectifying device that outputs DC power.

The distribution board 300 branches the electric power received from the power supply device 500, and supplies the branched electric power to the ICT device or the like.

The distribution board 300 includes a measurement unit 400. The measurement unit 400 acquires the voltage, current, power, and the like of the power input unit and the power output unit of the distribution board 300, and transmits the acquired information and the acquisition time (timestamp) to the monitoring device 100 via a measurement signal line (or a communication line). The measurement unit 400 does not need to be provided in the distribution board 300, for example, it maybe provided in the power supply device 500, it may be provided in a power receiving unit that receives the electric power supplied to the ICT device, or it maybe provided in a position other than these.

The ICT devices are, for example, servers, routers, switches, or the like. As illustrated in FIG. 1, the ICT devices include a power supply unit, a CPU, a memory, and an HDD (hard disk drive).

The power supply unit operates with the electric power received from the distribution board 300, and supplies electric power to the CPU, memory, and HDD. The ICT devices can monitor the processing amount such as the CPU usage rate, the memory usage rate, and the traffic amount, and transmits the processing amount information to the monitoring device 100 via the communication line. These pieces of information are the processing amount that can be easily obtained by normal operation. By utilizing the processing amount that can be easily acquired in normal operation, it is possible to eliminate the need for sensors for individually measuring the power consumption of the ICT devices.

The communication between the measurement unit 400 and the monitoring device 100 and the communication between the ICT devices and the monitoring device 100 may be performed via the measurement signal line or the communication line, or may be performed via wireless communication, or may be performed via a network such as the Internet.

(Monitoring Device)

As illustrated in FIG. 1, the monitoring device 100 includes a data processing unit 110 and a display unit 120. The data processing unit 110 includes a calculation unit 111, a storage unit 112, and a control unit 113. The data processing unit 110 may be referred to as a “calculation unit”.

The storage unit 112 stores data indicating the relationship between the processing amount and the power consumption amount. The storage unit 112 stores the power information and the time stamp data sent from the measurement unit 400, and the processing amount information and the time stamp data acquired from the ICT device 200. More specifically, the storage unit 112 stores the following information.

The storage unit 112 stores an ICT device efficiency characteristic table as data indicating the relationship between the processing amount and the power consumption amount, stores a power measurement table as the power information and the time stamp data, and stores an ICT device table as the processing amount information and the time stamp data.

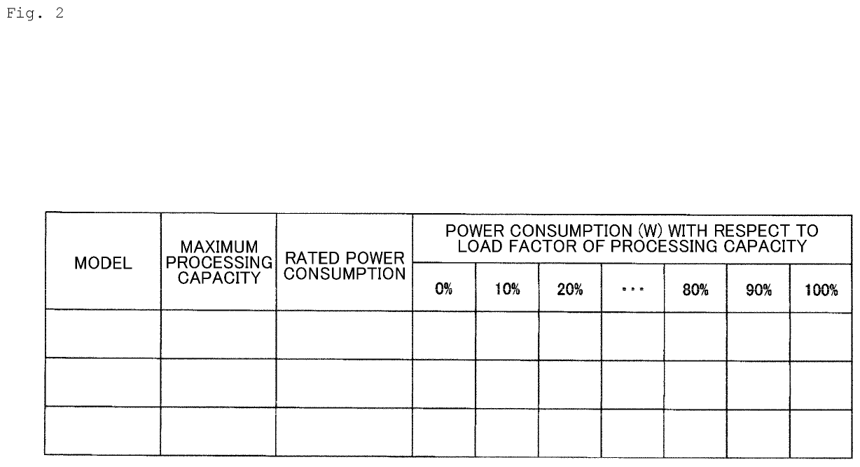

FIG. 2 illustrates a structural example of the ICT device efficiency characteristic table. As illustrated in FIG. 2, the ICT device efficiency characteristic table has “model”, “maximum processing capacity”, “rated power consumption”, and “power consumption with respect to load factor of processing capacity” as items.

The “model” is the model of an ICT device. The “maximum processing capacity” is the maximum processing capacity of the model, and is, for example, the maximum number of commands that can be processed per unit time when focusing on the processing amount of a CPU. The “rated power consumption” is the maximum power consumption. The “power consumption with respect to load factor of processing capacity” is the power consumption when performing processing of (maximum processing capacity)×(load factor (0%, 10%, and the like)).

The data of the ICT device efficiency characteristic table may be obtained in advance and stored in the storage unit 112 in advance, or may be calculated by the calculation unit 111 on the basis of the measurement data.

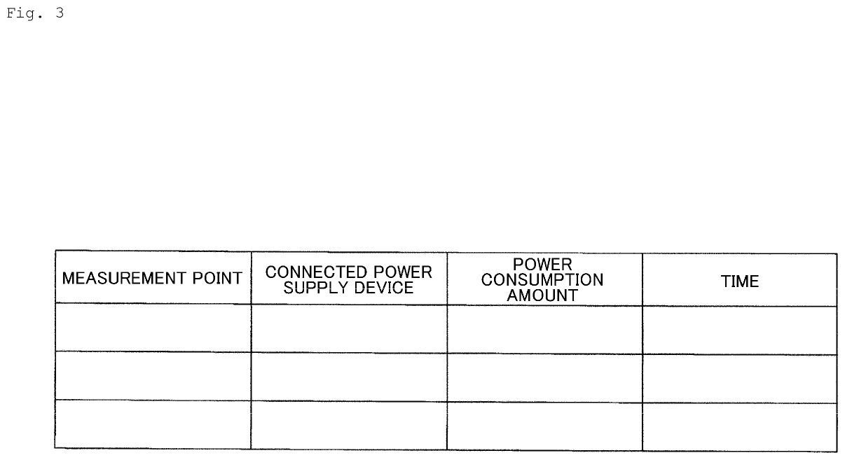

FIG. 3 illustrates the structure of the power measurement table. As illustrated in FIG. 3, the power measurement table has “measurement point”, “connected power supply device”, “power consumption amount”, and “time” as items. The “measurement point” indicates a point (place) where the distribution board to be measured by the measurement unit 400 is arranged. The “connected power supply device” indicates a power supply device to be measured.

The “power consumption amount” is the total value of the power consumption consumed by a plurality of ICT devices connected to the power supply device via the distribution board. This can be rephrased as “the total value of the electric power supplied to the plurality of ICT devices connected to the power supply device via the distribution board”. The “time” is a time stamp and indicates the time when the measurement was performed. The data of the power measurement table is data measured by the measurement unit 400 and acquired by the monitoring device 100.

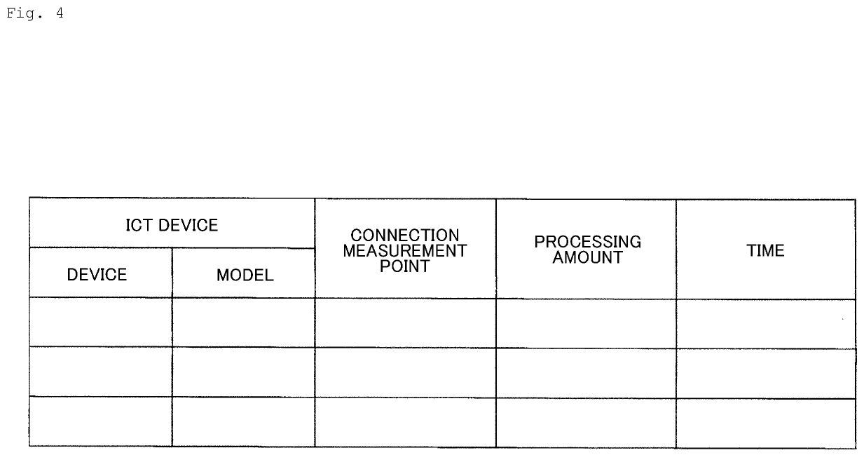

FIG. 4 illustrates the structure of the ICT device table. As illustrated in FIG. 4, the ICT device table has “ICT device” (“device”, “model”), “connection measurement point”, “processing amount”, and “time” as items.

The “ICT device” (“device”, “model”) indicates the identification information and model of the ICT device. The connection measurement point indicates a measurement point to which the corresponding ICT device is connected. The “processing amount” is a load factor (which may be referred to as a usage rate) indicating how much of the processing amount that the ICT device can handle at one time is used for processing. The “time” is a time stamp and indicates the time when the measurement was performed. The data of the ICT device table is data measured by the ICT device and acquired by the monitoring device 100.

The calculation unit 111 of the data processing unit 110 calculates the surplus power capacity on the basis of the information stored in the storage unit 112, and transmits the calculated surplus power capacity to the display unit 120 or the control unit 113. The display unit 120 displays the surplus power capacity. The control unit 113 controls the processing amount of the ICT device on the basis of the surplus power capacity. A method of calculating the surplus power capacity will be described later.

For example, when connecting a new ICT device, an operator (person) needs to check the surplus power capacity displayed on the display unit 120, and determines whether the current power supply device can supply the electric power and whether it is necessary to add a power supply device.

The control unit 113 controls one or a plurality of connected ICT devices so that the processing amount is within the range allowable by the surplus power capacity. For example, the control unit 113 controls the ICT device whose processing amount is larger than a predetermined value to reduce the packet processing speed or the like so that the processing amount is equal to or less than the predetermined value. By performing this processing on one or a plurality of ICT devices, the surplus power capacity of the power supply device becomes a sufficient surplus power capacity (for example, a surplus power capacity equal to or higher than a predetermined threshold value). In this way, it is possible to avoid the occurrence of a failure due to insufficient power supply capacity.

### Hardware Configuration Example

The monitoring device 100 can be realized by executing a program that describes the processing contents described in the present embodiment. The “computer” may be a physical machine or a virtual machine. When using a virtual machine, the “hardware” described here is virtual hardware.

The monitoring device 100 can be realized by executing a program corresponding to the processing executed by the monitoring device 100 using hardware resources such as a CPU and a memory built in the computer. The program can be recorded on a computer-readable recording medium (portable memory, and the like), stored, and distributed. It is also possible to provide the program through a network such as the Internet or an email.

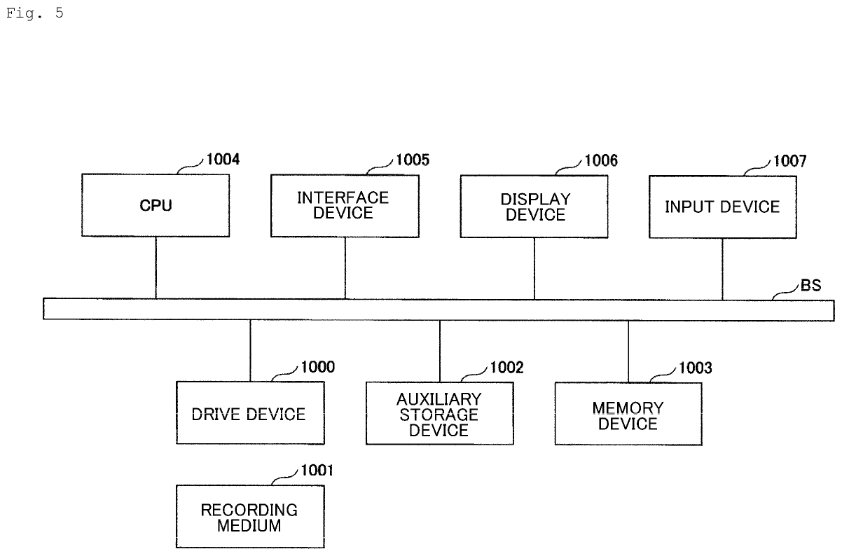

FIG. 5 is a diagram illustrating a hardware configuration example of the computer. The computer of FIG. 5 has a drive device 1000, an auxiliary storage device 1002, a memory device 1003, a CPU 1004, an interface device 1005, a display device 1006, an input device 1007, and the like, which are connected to each other by a bus B.

The program that realizes the processing in the computer is provided by, for example, a recording medium 1001 such as a CD-ROM or a memory card. When the recording medium 1001 storing the program is set in the drive device 1000, the program is installed in the auxiliary storage device 1002 from the recording medium 1001 via the drive device 1000. However, the program does not necessarily have to be installed from the recording medium 1001, and may be downloaded from another computer via the network. The auxiliary storage device 1002 stores the installed program and also stores necessary files, data, and the like.

The memory device 1003 reads and stores the program from the auxiliary storage device 1002 when there is a program activation instruction. The CPU 1004 realizes the function related to the monitoring device 100 according to the program stored in the memory device 1003. The interface device 1005 is used as an interface for connecting to a network. The display device 1006 displays a GUI (Graphical User Interface) or the like based on a program. The input device 1007 is configured of a keyboard, a mouse, buttons, a touch panel, and the like, and is used for inputting various operation instructions.

### Operation Example

Next, an operation example of the monitoring device 100 will be described. Operation example 1 and operation example 2 will be described below.

### Operation Example 1

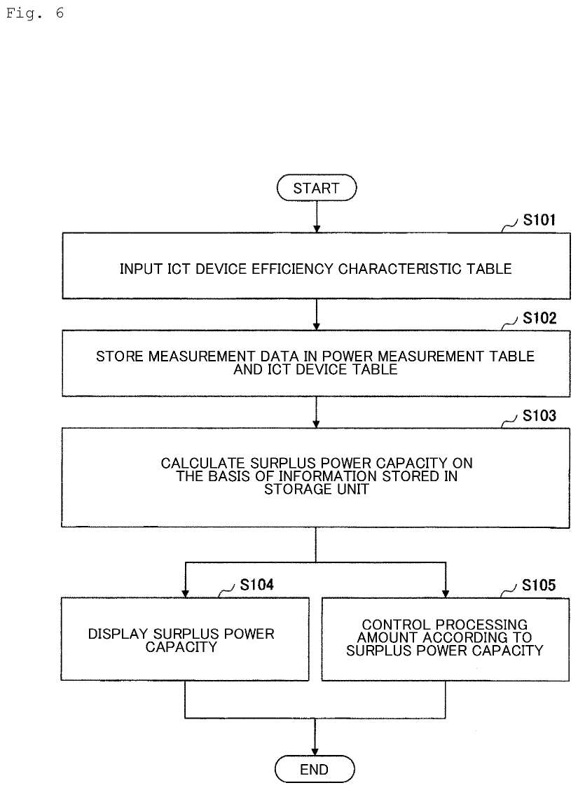

Operation example 1 will be described with reference to the flowchart of FIG. 6. In S101, the ICT device efficiency characteristic table is input to the data processing unit 110 and stored in the storage unit 112.

In S102, the measurement data obtained from the measurement unit 400 is input to the data processing unit 110 and stored in the power measurement table of the storage unit 112. The measurement data obtained from the ICT devices is input to the data processing unit 110 and stored in the ICT device table of the storage unit 112.

In S103, the calculation unit 111 calculates the surplus power capacity of the power supply device on the basis of the information stored in the storage unit 112.

More specifically, for example, the calculation unit 111 acquires the processing amount of the ICT devices, estimates the increase in power consumption when the ICT devices perform processing with the maximum processing amount on the basis of the processing amount, and subtracts the sum of the total value of the increase in power consumption of a plurality of target ICT devices and the total value of the electric power supplied to the plurality of ICT devices from the maximum power consumption amount of the power supply device to calculate the surplus power capacity.

In S104, the display unit 120 displays the surplus power capacity calculated in S103. In S105, the control unit 113 controls the processing amount of one or a plurality of ICT devices. Both S104 and S105 may be executed, or either of them may be executed.

### Operation Example 2

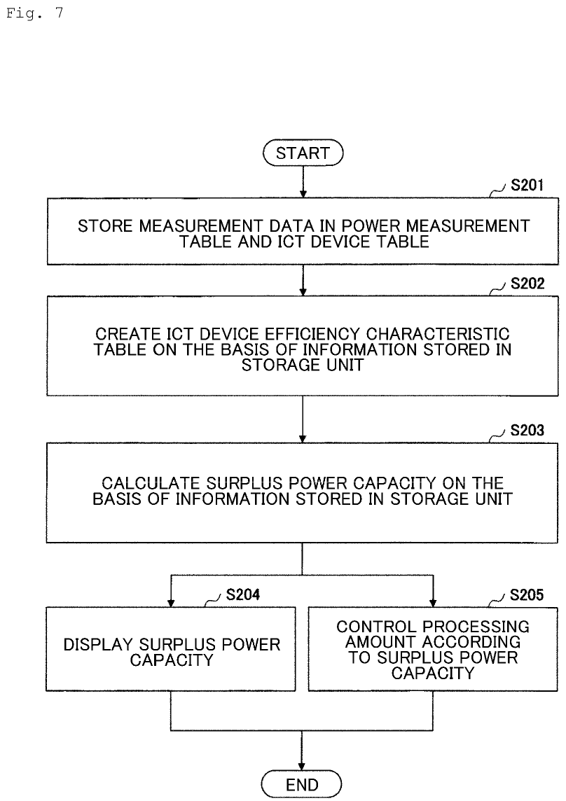

Operation example 2 will be described with reference to the flowchart of FIG. 7. In S201, the measurement data obtained from the measurement unit 400 is input to the data processing unit 110 and stored in the power measurement table of the storage unit 112. The measurement data obtained from the ICT devices is input to the data processing unit 110 and stored in the ICT device table of the storage unit 112.

In S201, the calculation unit 111 creates an ICT device efficiency characteristic table on the basis of the information stored in the storage unit 112 and stores it in the storage unit 112.

If there is a sufficient amount of data in the power measurement table and the ICT device table, it is possible to create the ICT device efficiency characteristic table without the power consumption data of individual ICT devices.

For example, it is assumed that, when the power supply device 500 supplies electric power to the ICT device 1, the ICT device 2, and the ICT device 3, the total value of the electric power supplied at a certain time T1 is 400 W, and the processing amounts of the ICT device 1, the ICT device 2, and the ICT device 3 at the time T1 are 20%, 20%, and 10%, respectively. It is also assumed that the total value of the electric power supplied at another time T2 is 500 W, and the processing amounts of the ICT device 1, the ICT device 2, and the ICT device 3 at the time T2 are 20%, 20%, and 20%, respectively. In this way, it can be calculated that the difference between the power consumption when the processing amount (load factor) in the ICT device 3 is 20% and the power consumption when the processing amount (load factor) is 10% is 100 W. Further, when the power consumption at the processing amounts of 30% and 50% in a certain ICT device is calculated, but the power consumption data at the processing amount of 40% in the ICT device is not calculated, the power consumption at the processing amount of 40% can be estimated by compensation from the power consumption at the processing amounts of 30% and 50%.

By accumulating the above-described calculations, it is possible to create an ICT device efficiency characteristic table without the power consumption data of individual ICT devices.

S203, S204, and S205 are the same as S103, S104, and S105 in Operation example 1, respectively.

### EXAMPLE

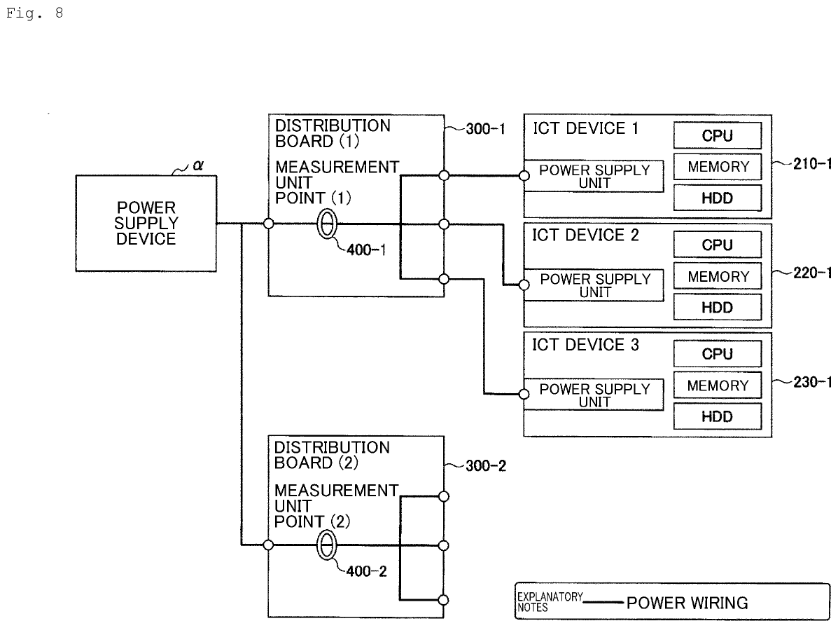

Next, an example of calculating the surplus power capacity by the monitoring device 100 will be described. In this example, for example, as illustrated in FIG. 8, distribution boards 300-1 and 300-2 are provided at a plurality of points (points (1) and (2) in the example of FIG. 8), and electric power is supplied from a power supply device α to the ICT devices 1 to 3 connected to the distribution board 300-1.

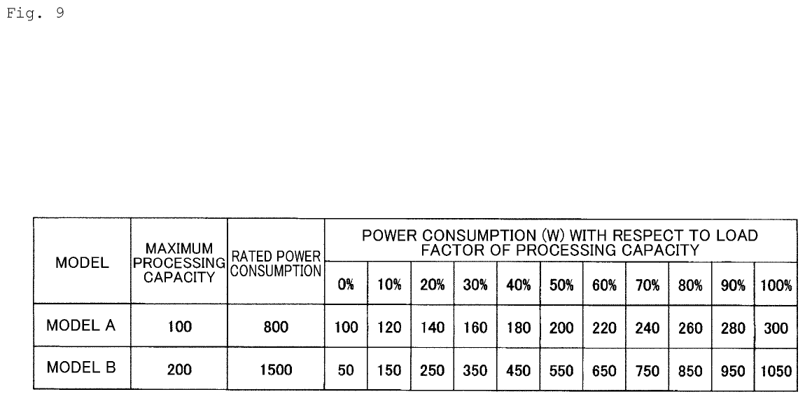

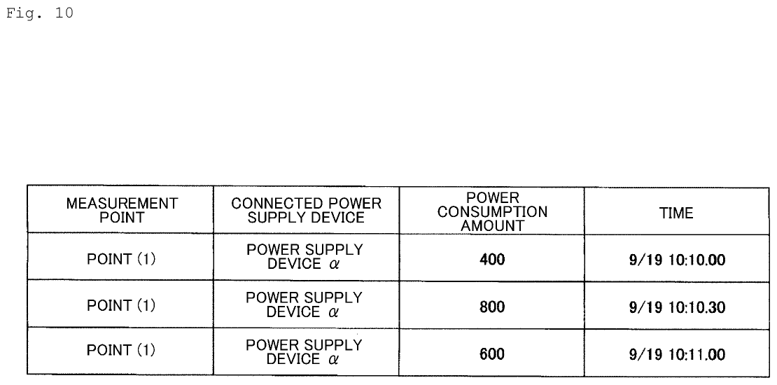

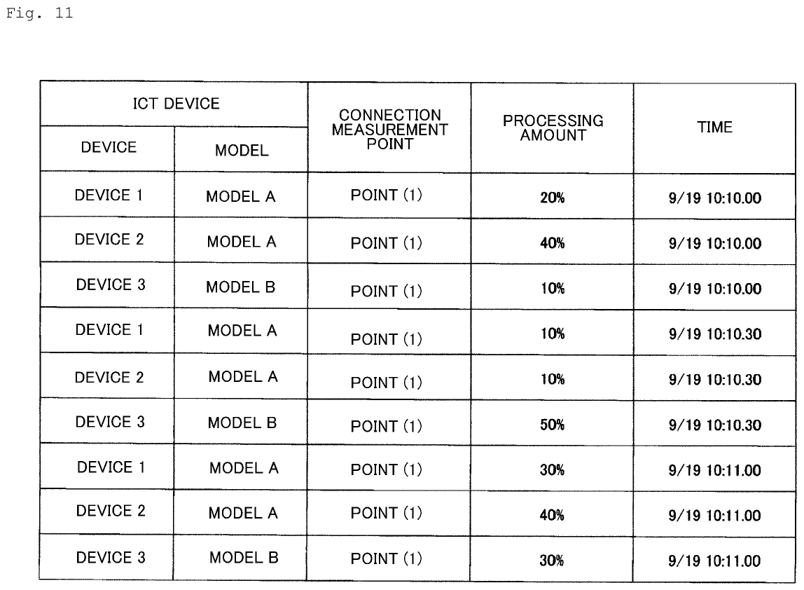

In this example, the storage unit 112 stores the ICT device efficiency characteristic table illustrated in FIG. 9, the power measurement table illustrated in FIG. 10, and the ICT device table illustrated in FIG. 11. The calculation unit 111 calculates the surplus power capacity of the power supply device a by referring to these tables. Hereinafter, calculation method example 1 and calculation method example 2 will be described. In this example, it is assumed that the power consumption amount of each ICT device depends only on the processing amount of a CPU. However, such an assumption is only an example.

### Calculation Method Example 1

In calculation method example 1, the calculation unit 111 calculates the surplus power capacity on the basis of the maximum value of the power consumption amount in the power measurement table (FIG. 10). Specifically, the surplus power capacity is calculated as follows.

By referring to the power measurement table (FIG. 10), the calculation unit 111 grasps that the maximum value of the power consumption amounts of the power supply device α (corresponding to the total value of the power consumption of the ICT devices 1 to 3) is 800 W at time “9/19 10:10.30”.

By referring to the ICT device table (FIG. 11), the calculation unit 111 grasps the processing amounts of the ICT devices at time “9/19 10:10.30”. Specifically, it is grasped that the processing amount of the ICT device 1 is 10%, the processing amount of the ICT device 2 is 10%, and the processing amount of the ICT device 3 is 50%.

By referring to the ICT device efficiency characteristic table (FIG. 9), the calculation unit 111 calculates the power consumption corresponding to the remaining processing capacity of the ICT devices at the time “9/19 10:10.30” (the power consumption that can be added to the power consumption at that time).

Specifically, since the processing amount of the ICT device 1 (model A) is 10%, the power consumption is 120 W from the ICT device efficiency characteristic table (FIG. 9). Since the power consumption is 300 W at the processing amount of 100%, the power consumption for the remaining processing amount of 90% is 300-120=180 W. Similarly, for the ICT device 2 (model A), the remaining power consumption is 180 W.

Since the processing amount of the ICT device 3 (model B) is 50%, the power consumption is 550 W from the ICT device efficiency characteristic table (FIG. 9). Since the power consumption is 1050 W at the processing amount of 100%, the power consumption for the remaining processing amount of 50% is 1050−550=500 W.

The power consumption of the power supply device a at time “9/19 10:10.30” (corresponding to the total power consumption of the ICT devices 1 to 3 at that time) is 800 W, and the total of the remaining power consumption is 180+180+500=860 W. Therefore, the total thereof 860 W+800 W=1660 W is the power consumption amount when the maximum processing amount is reached.

The calculation unit 111 calculates the surplus power capacity by subtracting 1660 W from the maximum power consumption amount of the power supply device α. For example, assuming that the maximum power consumption amount of the power supply device α is 2000 W, the surplus power capacity is 2000 W−1660 W=340 W. The maximum power consumption amount of the power supply device α may be rephrased as the maximum power supply amount of the power supply device α.

### Calculation Method Example 2

In calculation method example 2, the calculation unit 111 calculates the surplus power capacity on the basis of the average value within a certain period of the power consumption amount in the power measurement table (FIG. 10). Specifically, the surplus power capacity is calculated as follows.

By referring to the power measurement table (FIG. 10), the calculation unit 111 calculates the average value of the power consumption amount of the power supply device α in “9/19 10:10.00” to “9/19 10:11.00” as (400+800+600)/3=600 W.

Referring to the ICT device table (FIG. 11), the calculation unit 111 calculates the average value of the processing amounts of the ICT devices in the same period “9/19 10:10.00” to “9/19 10:11.00” as the above-mentioned period.

For example, the average value of the processing amount of the ICT device 1 is (20+10+30)/3=20%. Similarly, the average value of the processing amount of the ICT device 2 is (40+10+40)/3=30%, and the average value of the processing amount of the ICT device 3 is (10+50+30)/3=30%.

By referring to the ICT device efficiency characteristic table (FIG. 9), the calculation unit 111 calculates the remaining processing capacity (power consumption that can be added to the average power consumption) of the ICT devices.

Specifically, since the average value of the processing amount of the ICT device 1 (model A) is 20%, the power consumption is 140 W from the ICT device efficiency characteristic table (FIG. 9). Since the power consumption is 300 W at the processing amount of 100%, the power consumption for the remaining processing amount of 80% is 300−140=160 W.

Since the average value of the processing amount of the ICT device 2 (model A) is 30%, the power consumption is 160 W from the ICT device efficiency characteristic table (FIG. 9). Since the power consumption is 300 W at the processing amount of 100%, the power consumption for the remaining processing amount of 70% is 300−160=140 W.

Since the average value of the processing amount of the ICT device 3 (model B) is 30%, the power consumption is 350 W from the ICT device efficiency characteristic table (FIG. 9). Since the power consumption is 1050 W at the processing amount of 100%, the power consumption for the remaining processing amount of 70% is 1050−350=700 W.

The average value of the power consumption amount of the power supply device a (corresponding to the total power consumption of the ICT devices 1 to 3) is 600 W, and the total of the remaining power consumption is 140+160+700=1000 W. Therefore, the total thereof 1000 W+600 W=1600 W is the power consumption amount when the maximum processing amount is reached.

The calculation unit 111 calculates the surplus power capacity by subtracting 1600 W from the maximum power consumption of the power supply device α. For example, assuming that the maximum power consumption of the power supply device α is 2000 W, the surplus power capacity is 2000 W−1600 W=400 W.

### Effect of Embodiment

As described above, according to the technique according to the present embodiment, it is possible to obtain the surplus power capacity of a power supply device without individually measuring the power consumption of a plurality of ICT devices in a power supply device that supplies electric power to the plurality of ICT devices.

Thereby, for example, it is possible to optimize the timing to add an ICT device constituting a communication service and a power supply device for supplying electric power to the ICT device. Further, for example, it is possible to avoid excessive investment and prevent a power failure due to a shortage of power supply.

### Summary of Embodiment

This specification describes at least the surplus power capacity calculation system, the monitoring device, the surplus power capacity calculation method, and the program described in the following items.

### (Item 1)

A surplus power capacity calculation system including:

a measurement unit that measures a total value of electric power supplied from a power supply device to a plurality of ICT devices; and

a monitoring device that calculates a surplus power capacity of the power supply device, wherein the monitoring device includes:

a calculation unit that acquires the total value and a processing amount of each of the plurality of ICT devices, estimates an increase in power consumption on the basis of the processing amount when each ICT device performs processing with a maximum processing amount, and subtracts a sum of the increase and the total value from a maximum power consumption amount of the power supply device to calculate the surplus power capacity.

### (Item 2)

The surplus power capacity calculation system according to item 1, wherein

the monitoring device further includes a storage unit that stores a table indicating correspondence between a load factor corresponding to the processing amount of the ICT device and the power consumption of the ICT device, and

the calculation unit calculates the increase by subtracting the power consumption corresponding to the processing amount from the power consumption corresponding to a maximum load factor by referring to the table for each of the ICT devices.

### (Item 3)

The surplus power capacity calculation system according to item 1 or 2, wherein

the monitoring device further includes a display unit that displays the surplus power capacity.

### (Item 4)

The surplus power capacity calculation system according to any one of items 1 to 3, wherein

the monitoring device further includes a control unit that controls the processing amount of the ICT device on the basis of the surplus power capacity.

### (Item 5)

A surplus power capacity calculation method executed by a surplus power capacity calculation system including a measurement unit that measures a total value of electric power supplied from a power supply device to a plurality of ICT devices; and a monitoring device that calculates a surplus power capacity of the power supply device, wherein

the monitoring device executes:

acquiring the total value and a processing amount of each of the plurality of ICT devices, estimating an increase in power consumption on the basis of the processing amount when each ICT device performs processing with a maximum processing amount, and subtracting a sum of the increase and the total value from a maximum power consumption amount of the power supply device to calculate the surplus power capacity.

### (Item 6)

A monitoring device in a surplus power capacity calculation system including a measurement unit that measures a total value of electric power supplied from a power supply device to a plurality of ICT devices; and the monitoring device that calculates a surplus power capacity of the power supply device, including:

a calculation unit that acquires the total value and a processing amount of each of the plurality of ICT devices, estimates an increase in power consumption on the basis of the processing amount when each ICT device performs processing with a maximum processing amount, and subtracts a sum of the increase and the total value from a maximum power consumption amount of the power supply device to calculate the surplus power capacity.

### (Item 7)

The monitoring device according to item 6, further including: a control unit that controls the processing amount of the ICT device on the basis of the surplus power capacity.

### (Item 8)

A program for causing a computer to function as each unit of the monitoring device according to item 6 or 7.

While embodiments of the present invention have been described, the present invention is not limited to the above-described specific embodiments, and various modifications and changed can be made without departing from the spirit of the present invention described in the claims.

### REFERENCE DOCUMENT

Reference Document 1: SPECpower web site
“https://www.spec.org/power ssj2008/results/”
Reference Document 2: NTT docomo web site
“https://www.nttdocomo.co.jp/corporate/technology/rd/tech/nfv/nfv01/02/index.html”
Reference Document 3: NTT docomo web site
“https://www.nttdocomo.co.jp/corporate/technology/rd/tech/nfv/nfv01/05/03.html”

### REFERENCE SIGNS LIST

100 Monitoring device
110 Data processing unit
111 Calculation unit
112 Storage unit
113 Control unit
120 Display unit
210 to 230 ICT device
300 Distribution board
400 Measurement unit
500 Power supply device
α Power supply device
1000 Drive device
1001 Recording medium
1002 Auxiliary storage device
1003 Memory device
1004 CPU
1005 Interface device
1006 Display device
1007 Input device

1. A surplus power capacity calculation system comprising:
a measurement unit, including one or more processors, configured to measure a total value of electric power supplied from a power supply device to a plurality of ICT devices; and
a monitoring device for calculating a surplus power capacity of the power supply device, wherein
the monitoring device includes:
a calculation unit, including one or more processors, configured to acquire the total value and a processing amount of each of the plurality of ICT devices, estimate an increase in power consumption on the basis of the processing amount when each ICT device performs processing with a maximum processing amount, and subtract a sum of the increase and the total value from a maximum power consumption amount of the power supply device to calculate the surplus power capacity.

2. The surplus power capacity calculation system according to claim 1, wherein
the monitoring device further includes a storage unit, including one or more processors, configured to store a table indicating correspondence between a load factor corresponding to the processing amount of the ICT device and the power consumption of the ICT device, and
the calculation unit is configured to calculate the increase by subtracting the power consumption corresponding to the processing amount from the power consumption corresponding to a maximum load factor by referring to the table for each of the ICT devices.

3. The surplus power capacity calculation system according to claim 1, wherein
the monitoring device further includes a display unit that includes one or more processors and is configured to display the surplus power capacity.

4. The surplus power capacity calculation system according claim 1, wherein
the monitoring device further includes a control unit that includes one or more processors and is configured to control the processing amount of the ICT device on the basis of the surplus power capacity.

5. A surplus power capacity calculation method executed by a surplus power capacity calculation system including a measurement unit for measuring a total value of electric power supplied from a power supply device to a plurality of ICT devices and a monitoring device for calculating a surplus power capacity of the power supply device, the surplus power capacity calculation method comprising:
by the monitoring device, acquiring the total value and a processing amount of each of the plurality of ICT devices, estimating an increase in power consumption on the basis of the processing amount when each ICT device performs processing with a maximum processing amount, and subtracting a sum of the increase and the total value from a maximum power consumption amount of the power supply device to calculate the surplus power capacity.

6. A monitoring device in a surplus power capacity calculation system including a measurement unit for measuring a total value of electric power supplied from a power supply device to a plurality of ICT devices, the monitoring device being configured to calculate a surplus power capacity of the power supply device, and comprising:
a calculation unit, including one or more processors, configured to acquire the total value and a processing amount of each of the plurality of ICT devices, estimate an increase in power consumption on the basis of the processing amount when each ICT device performs processing with a maximum processing amount, and subtract a sum of the increase and the total value from a maximum power consumption amount of the power supply device to calculate the surplus power capacity.

7. The monitoring device according to claim 6, further comprising:
a control unit, including one or more processors, configured to control the processing amount of the ICT device on the basis of the surplus power capacity.

8. A non-transitory computer readable medium storing a program for causing a computer to function as each unit of the monitoring device according to claim 6.

9. A non-transitory computer readable medium storing a program for causing a computer to function as each unit of the monitoring device according to claim 7.

10. The surplus power capacity calculation method according to claim 5, further comprising:
by the monitoring device, storing a table indicating correspondence between a load factor corresponding to the processing amount of the ICT device and the power consumption of the ICT device, and calculating the increase by subtracting the power consumption corresponding to the processing amount from the power consumption corresponding to a maximum load factor by referring to the table for each of the ICT devices.

11. The surplus power capacity calculation method according to claim 5, further comprising:
displaying, by the monitoring device, the surplus power capacity.

12. The surplus power capacity calculation method according to claim 5, further comprising:
controlling, by the monitoring device, the processing amount of the ICT device on the basis of the surplus power capacity.
